(19) United States
(12) Patent Application Publication
(10) Pub. No.: US 2026/0188628 A1
(43) Pub. Date: Jul. 2, 2026

(54) SYSTEMS AND METHODS FOR CONTROLLING TILTS ACROSS A SURFACE OF A SUBSTRATE

(71) Applicant: Lam Research Corporation, Fremont, CA (US)

(72) Inventors: Arthur M. HOWALD, Livermore, CA (US); William Dean THOMPSON, Pleasanton, CA (US); Bing JI, Pleasanton, CA (US); Dong Woo PAENG, Albany, CA (US); John Patrick HOLLAND, San Jose, CA (US); Andrew D. BAILEY, III, Milpitas, CA (US)

(21) Appl. No.: 19/131,524

(22) PCT Filed: Nov. 10, 2023
(86) PCT No.: PCT/US2023/079403

§ 371 Date: May 20, 2025

Related U.S. Application Data
(60) Provisional application No. 63/427,772, filed on Nov. 23, 2022.

(51) Int. Cl. H01J 37/32; H10P 95/00

(52) U.S. Cl. CPC H01J 37/3266; H01J 37/32091; H01J 37/32568; H10P 95/00

(57) ABSTRACT

Systems and methods for controlling tilt across a surface of a substrate are described. One of the methods includes providing a current signal to a magnetic coil associated with a plasma chamber. The current signal produces a magnetic field within the plasma chamber. The method further includes controlling a direct current (DC) power source to output a plurality of magnitudes of the current signal in a pulsed manner during a clock cycle. The method includes repeating the plurality of magnitudes of the current signal with each additional clock cycle.

### FIELD

The present embodiments relate to systems and methods for controlling tilts across a surface of a substrate.

### BACKGROUND

A plasma tool includes a radio frequency (RF) generator, a match, and a plasma chamber. A substrate is placed in the plasma chamber for etching. The RF generator generates an RF signal, which is sent via the match to the plasma chamber. When a gas is supplied to the plasma chamber, power of the RF signal interacts with the gas to strike plasma within the plasma chamber. The plasma is used to process the substrate. The substrate is etched to generate features within the substrate.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for controlling tilts across a surface of a substrate, such as a semiconductor wafer. It should be appreciated that the present embodiments can be implemented in numerous ways, e.g., a process, an apparatus, a system, a device, or a method on a computer readable medium. Several embodiments are described below.

In an embodiment, a direct current (DC) magnetic coil produces a small magnetic field, having a few Gauss, at the semiconductor wafer and can tune tilts near a center of the wafer. For example, a portion of the magnetic field at the center is vertical and tunes tilts near the center of the wafer. The magnetic field introduces a tilt component in an azimuthal direction on the wafer for slit etch processes. The tilt component is created by a radial component of the magnetic field and the radial component increases radially outwards from the center of the wafer. The tilt component can be reduced, such as removed, by applying the systems and methods, described herein. The systems and methods are applied to alternate a variable, such as a magnitude of the magnetic field or a polarity of the magnetic field or a time period for which the magnetic field is applied or a combination thereof. For example, the tilt component is reduced by switching the polarity every minute or so during the slit etch processes. To illustrate, the polarity is switched at recipe step boundaries, which for some recipes are about a minute apart. To further illustrate, a first polarity is applied during a first recipe step and a second polarity is applied during a second recipe step. The first polarity is opposite compared to the second polarity. As another further illustration, the first polarity is applied for a shorter time period compared to a time period of application of the second polarity or vice versa. As another illustration, each recipe step is broken into 2 or more sub-steps and the polarity is switches between the sub-steps. As yet another illustration, the polarity is switched at fixed time intervals that are not necessarily aligned with any recipe step.

In one embodiment, a method for controlling tilt across a surface of a substrate is described. The method includes providing a current signal to a magnetic coil associated with a plasma chamber. The current signal produces a magnetic field within the plasma chamber. The method further includes controlling a DC power source to output a plurality of magnitudes of the current signal in a pulsed manner during a clock cycle. The method includes repeating the plurality of magnitudes of the current signal with each additional clock cycle.

In an embodiment, a method for controlling tilt across a surface of a substrate is described. The method includes providing a current signal to a magnetic coil associated with a plasma chamber. The current signal produces a magnetic field within the plasma chamber. The method includes controlling a DC power source to output a plurality of magnitudes of the current signal in a pulsed manner during a clock cycle. The plurality of magnitudes is output at a beginning of a process operation. The method includes repeating the plurality of magnitudes of the current signal at a beginning of each additional process operation.

In one embodiment, a method for controlling tilt across a surface of a substrate is described. The method includes providing a current signal to a magnetic coil associated with a plasma chamber. The current signal produces a magnetic field within the plasma chamber. The method includes controlling a DC power source to output a plurality of magnitudes of the current signal in a pulsed manner during a clock cycle. Each of the plurality of magnitudes is output during a process operation. The method includes repeating the plurality of magnitudes of the current signal during each additional process operation.

Several advantages of the herein described systems and methods for controlling tilt across the surface of the substrate include modifying the variable of a current signal that is supplied to the magnetic coil associated with a plasma chamber. The variable is modified in a pulsed manner to create a series of magnitudes and a series of transitions from one magnitude to another of the current signal. By modifying the variable, tilts across a top surface of the semiconductor wafer are controlled to reduce, such as remove, the tilts. As an example, a global tilt range across the top surface of the semiconductor wafer is decreased from a range of 71 nanometers (nm) to 87 nanometers to about 51 nanometers and tilt symmetry across the top surface of the wafer is increased.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system to illustrate use of a magnetic coil to control tilt across a surface of a substrate.

FIG. 2 is an embodiment of a graph to illustrate parameters of process operations, such as recipe steps, during each cycle of a clock signal.

FIG. 3 is an embodiment of a graph to illustrate that a magnitude or a polarity or a combination thereof of a current signal is modified periodically.

FIG. 4 is an embodiment of a graph to illustrate that a magnitude or polarity or a combination thereof of a current signal is modified at an end or a beginning of each process operation.

FIG. 5 is an embodiment of a graph to illustrate that a magnitude or polarity or a combination thereof of a current signal is modified during each process operation.

FIG. 6A is an embodiment of a graph to illustrate another manner in which a magnitude or a polarity or a combination thereof of a current signal is modified periodically.

FIG. 6B is an embodiment of a graph to illustrate yet another manner in which a magnitude or a polarity or a combination thereof of a current signal is modified periodically.

FIG. 6C is an embodiment of a graph to illustrate still another manner in which a magnitude or a polarity or a combination thereof of a current signal is modified periodically.

FIG. 6D is an embodiment of a graph to illustrate another manner in which a magnitude or a polarity or a combination thereof of a current signal is modified periodically.

FIG. 6E is an embodiment of a graph to illustrate still another manner in which a magnitude or a polarity or a combination thereof of a current signal is modified periodically.

FIG. 6F is an embodiment of a graph to illustrate yet another manner in which a magnitude or a polarity or a combination thereof of a current signal is modified periodically.

FIG. 7 is a diagram of an embodiment of a system to illustrate a direct current (DC) power supply for generating a current magnitude signal.

FIG. 8 is a diagram of an embodiment of a system to illustrate a polarity modifier circuit.

### DETAILED DESCRIPTION

The following embodiments describe systems and methods for controlling tilts across a surface of a substrate. It will be apparent that the present embodiments may be practiced without some or all of these specific details. In other instances, well known operations have not been described in detail in order not to unnecessarily obscure the present embodiments.

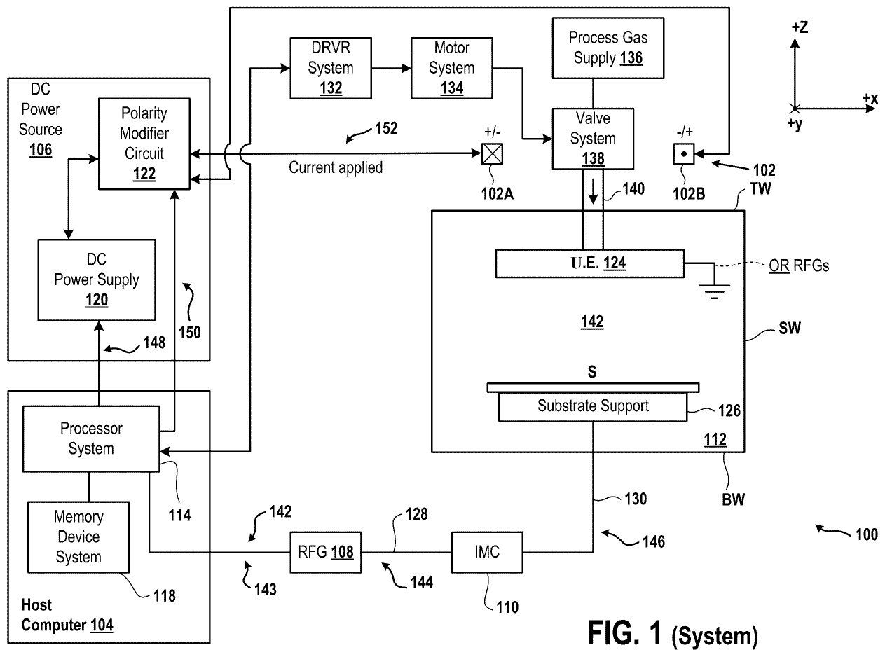

FIG. 1 is a diagram of an embodiment of a system 100 to illustrate use of a magnetic coil 102 to control tilts across a surface of a substrate S. The system 100 includes a host computer 104, a direct current (DC) power source 106, a radio frequency (RF) generator (RFG) 108, an impedance matching circuit (IMC) 110, and a plasma chamber 112. The host computer 104 includes a processor system 114 and a memory device system 118. Also, the DC power source 106 includes a DC power supply 120 and a polarity modifier circuit 122. The plasma chamber 112 includes an upper electrode 124 and a substrate support 126. The system 100 further includes a driver system 132, a motor system 134, a process gas supply 136, and a valve system 138.

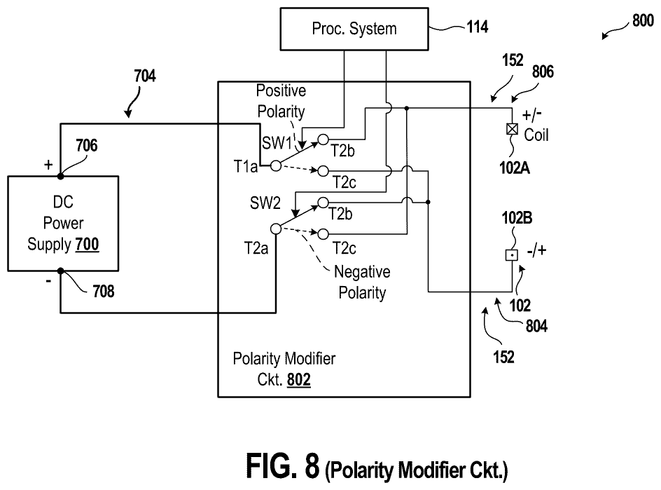

Examples of a host computer, as used herein, include a desktop computer, a controller, laptop computer, a tablet, and a smart phone. An example of the DC power supply 120 is a series of cells, such as a series of batteries. An example of the polarity modifier circuit 122 is described below with reference to FIG. 8. The processor system 114 includes one or more processors and the memory device system 118 includes one or more memory devices. As an example, a processor is an application specific integrated circuit (ASIC), a central processing unit (CPU), a field programmable gate array (FPGA), a microprocessor, a programmable logic device (PLD), an integrated controller, or a microcontroller. Examples of a memory device, as used herein, include a read-only memory (ROM) and a random-access memory (RAM). To illustrate, the memory device is a flash memory or a redundant array of independent discs (RAID).

As an example, the magnetic coil 102 is a coil having one or more turns. For example, the magnetic coil 102 is different from a transformer coupled plasma (TCP) coil. To illustrate, the magnetic coil 102 has multiple turns of copper wire and the TCP coil is a solid piece of copper. As another example, the magnetic coil 102 is not the TCP coil. The magnetic coil 102 has a terminal 102A and another terminal 102B. The terminal 102B is reached after traversing a portion of a turn from the terminal 102A. To illustrate, the magnetic coil 102 is fabricated from a metal, such as copper. To further illustrate, the magnetic coil 102 does not facilitate generation of plasma within the plasma chamber 112. An example of the substrate support 126 is an electrostatic chuck (ESC) and an example of the substrate S is a semiconductor wafer. To illustrate, the substrate support 126 has a lower electrode embedded within it. An example of the plasma chamber 112 is a capacitively coupled plasma (CCP) chamber. The plasma chamber 112 includes a top wall TW, a sidewall SW, and a bottom wall BW. The top wall TW is fitted to the side wall SW, which is fitted to the bottom wall BW. Also, the top wall TW is located above the bottom wall BW.

Also, as an example, the RF generator 108 is an RF generator that operates at a frequency of 100 kilohertz (kHz) or an RF generator that operates at a frequency of 400 kHz or is an RF generator that operates at a frequency of 2 megahertz (MHz) or an RF generator that operates at a frequency of 27 MHz or an RF generator that operates at a frequency of 60 MHz. An example of the impedance matching circuit 110 is an impedance matching network or a match or a match circuit. To illustrate, the impedance matching circuit 110 includes a network of electronic components, such as capacitors and inductors, that are coupled to each other. To further illustrate, the impedance matching circuit 110 includes one or more series electronic components or one or more shunt electronic components or a combination thereof.

An example of the driver system 132 includes one or more drivers, such as one or more transistors. Moreover, an example of the motor system 134 includes one or more electric motors. An example of the process gas supply 136 is one or more containers for storing one or more process gases, such as an oxygen containing gas, a nitrogen containing gas, and a fluorine containing gas. An example of the valve system 138 includes one or more valves. To illustrate, each valve is coupled to a corresponding one of the containers of the process gas supply 136.

The processor system 114 is coupled to the memory device system 118, to the DC power supply 120, and to the polarity modifier circuit 122. Moreover, the DC power supply 120 is coupled to the polarity modifier circuit 122, which is coupled to the magnetic coil 102. The magnetic coil 102 is associated with the plasma chamber 112. For example, the magnetic coil 102 is located outside the plasma chamber 112 above the top wall TW. Also, to illustrate, a plane passing through the turn of the magnetic coil 102 is along, such as substantially parallel to, the top wall TW. To further illustrate, the plane passing through the magnetic coil 102 is parallel to the top wall TW. The upper electrode 124 is located above the substrate support 126 and below the top wall TW.

The processor system 114 is coupled to the RF generator 108. The RF generator 108 is coupled via an RF cable 128 to the impedance matching circuit 110, which is coupled via an RF transmission line 130 to the lower electrode of the substrate support 126. The substrate S is placed on a top surface of the substrate support 126.

The processor system 114 is coupled to the driver system 132, which is coupled to the motor system 134. For example, each driver of the driver system 132 is coupled to a respective one of the electric motors of the motor system 134. Also, the motor system 134 is coupled to the valve system 138. As an example, each electric motor is coupled to a respective one of the valves of the valve system 138. The valve system 138 is coupled via a gas supply line 140 and the upper electrode 124 to a gap 142 between the upper electrode 124 and the substrate support 126. The gap 142 is formed within the plasma chamber 112 and the substrate S is placed within the gap 142.

The processor system 114 generates a recipe signal 142 and sends the recipe signal 142 to the RF generator 108. As an example, the recipe signal 142 includes one or more power levels. Each power level is an amount of power to be supplied by the RF generator 108. After receiving the recipe signal 142 and in response to receiving a trigger signal 143 from the processor system 114, the RF generator 108 generates an RF signal 144 based on the recipe signal 142. For example, the RF signal 144 has the one or more power levels. The RF generator 108 sends the RF signal 144 via the RF cable 128 to the impedance matching circuit 110.

Upon receiving the RF signal 144, the impedance matching circuit 110 matches an impedance of a load coupled to an output of the impedance matching circuit 110 with an impedance of a source coupled to an input of the impedance matching circuit 110 to modify an impedance of the RF signal 144. An example of the load includes the RF transmission line 130 and the plasma chamber 112 and an example of the source includes the RF cable 128 and the RF generator 108. The impedance of the RF signal 144 is modified to output a modified RF signal 146. The modified RF signal 146 is sent from the output of the impedance matching circuit 110 to the lower electrode of the substrate support 126.

Also, while the modified RF signal 146 is being supplied, the processor system 114 sends a control signal to the driver system 132. Upon receiving the control signal, each driver of the driver system 132 generates a respective current signal and provides the respective current signal to the respective one of the electric motors. Upon receiving the current signal, the electric motor rotates to operate, such as open or close or partially open, the respective one of the valves of the valve system 138 to control a supply of a respective one of the process gases from the process gas supply 130 via the valve, the gas supply line 140 and the upper electrode 124 to the gap 142. For example, when the valve is open or partially open, the process gas is supplied to the gap 142 from the process gas supply 136. On the other hand, when the valve is closed, the supply of the process gas from the process gas supply 136 to the gap 142 is cut off.

When the one or more process gases are supplied in addition to the modified RF signal 146 to the plasma chamber 112, plasma is created or maintained within the gap 142 to process the substrate S. Examples of processing the substrate S include depositing a material on the substrate S, etching to fabricate features, such as channels or trenches, within the substrate S, and cleaning the substrate S. Each feature has a tilt. For example, a side wall of each feature is tilted and is not vertical. To illustrate, an acute angle is formed with respect to a vertical line by a surface of the side wall. As another illustration, an acute angle is formed by a line connecting a center of a top plane, having an opening, of the feature and a center of a bottom wall of the feature with respect to the vertical line. The side wall of the feature is adjacent to the bottom wall and the top plane is adjacent to the side wall. Also, the top plane is above the bottom wall.

Moreover, during a time period in which the one or more process gases are supplied in addition to the modified RF signal 146 to the plasma chamber 112, the processor system 114 generates and sends one or more control signals 148, such as one or more on control signals or one or more off control signals or a combination thereof, to the DC power supply 120 and one or more position control signals 150 to the polarity circuit 122. As an example, the one or more control signals 148 are generated based on one or more magnitudes of one or more current values of a current signal 152 to be output from the DC power source 106 and respective one or more durations of the one or more magnitudes of the current signal 152. To illustrate, each magnitude of a current value is represented as a magnitude level. In the example, the one or more position control signals 150 are generated based on one or more polarities, such as positive or negative, of the one or more magnitudes of the current signal 152.

Also, during the time period in which the one or more process gases are supplied in addition to the modified RF signal 146 to the plasma chamber 112, upon receiving the one or more control signals 148 and the one or more position control signals 150, the DC power source 106 generates the current signal 152 having the one or more magnitudes, the one or more durations of the one or more magnitudes, and the one or more polarities of the one or more magnitudes. The current signal 152 is sent from the DC power source 106 to the magnetic coil 102. When the current signal 152 passes via the magnetic coil, such as from the terminal 102A to the terminal 102B or from the terminal 102B to the terminal 102A, a magnetic field is generated within the gap 142.

The magnetic field modifies the tilts of the features of the substrate S. For example, the tilts of the features across a top surface of the substrate S are modified to be symmetric. As another example, the tilts are modified to be reduced to zero or within a predetermined threshold from zero.

In one embodiment, instead of the magnetic coil 102 having the turn, another magnetic coil having more than one turn is used.

In an embodiment, more than one magnetic coil is used in the system 100.

In one embodiment, the magnetic coil 102 is located within the plasma chamber 112 to be associated with the plasma chamber 112. For example, the magnetic coil 102 is mounted on a pedestal (not shown) to which the upper electrode is secured. The upper electrode is located below the pedestal.

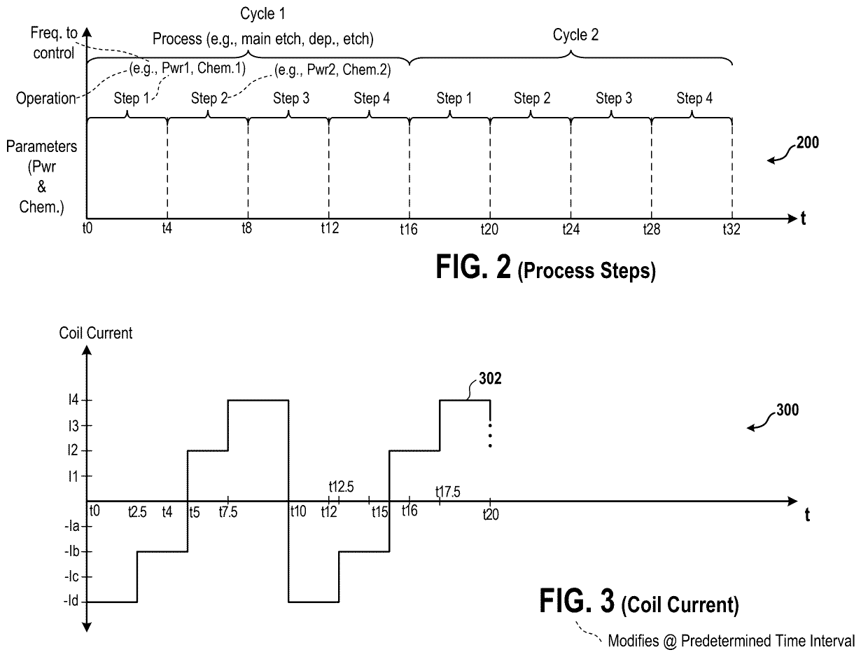

FIG. 2 is an embodiment of a graph 200 to illustrate parameters of multiple process operations during each cycle of a clock signal, such as a digital pulse signal. The clock signal is generated by the processor system 114 (FIG. 1) to have multiple clock cycles, such as a clock cycle 1, a clock cycle 2, and so on. For example, the processor system 114 includes a clock oscillator that generates the clock signal. Examples of the parameters include a chemistry of the one or more process gases and a power level of the RF signal 144 (FIG. 1). As an example, the chemistry includes one of the process gases or a mixture of two or more of the process gases. To illustrate, a chemistry m is different from a chemistry (m+1), where m is zero or a positive integer. To further illustrate, the chemistry m includes an oxygen-containing gas and the chemistry (m+1) includes a nitrogen-containing gas. As another further illustration, the chemistry m includes a first mixture of two or more process gases and the chemistry (m+1) includes a second mixture of two or more process gases. At least one of the process gases of the first mixture is different from at least one of the process gases of the second mixture.

As an example, a power level (m+1) is unequal to a power level m, where m is the positive integer. For example, the power level 2 is greater than or less than the power level 1, and the power level 3 is greater than or less than each of the power levels 1 and 2. As an example each power level includes a statistical power amount, such as a mean or a median of multiple power amounts. Also, as an example, all power amounts of the power level m are exclusive of all power amounts of the power level (m+1). To illustrate, the first power level includes a first statistical power amount of a first group of power amounts and the second power level includes a second statistical power amount of a second group of power amounts. A maximum of the first group is less than a minimum of the second group for the second power level to be greater than the first power level.

The graph 200 plots the parameters on a y-axis and time t on an x-axis. The time t ranges from a time t0 to a time t32. The range from the time t0 to the time t32 includes a time t1, a time t2, a time t3, a time t4, and so on until the time t32. It should be noted that a time interval between any two consecutive times is equal. For example, a time interval between the times t0 and t1 is equal to a time interval between the times t1 and t2. Also, as an example, a time period between the times t0 and t4 is a minute, a time period between the times t4 and t8 is a minute, and so on.

During the time interval between the times t0 and t4, the processor system 114 controls the valve system 138 (FIG. 1) to provide a chemistry 1 of the one or more process gases via the gas supply line 140 (FIG. 1) to the gap 142 (FIG. 1), or controls the RF generator 108 to generate a power level 1 of the RF signal 144, or a combination thereof to execute a first process operation. An example of the first process operation is a recipe step 1. To illustrate, during the first process operation, the substrate S is processed in a first manner, such as etched. Similarly, during the time interval between the times t4 and t8, the processor system 114 controls the valve system 138 to provide a chemistry 2 of the one or more process gases via the gas supply line 140 to the gap 142, or controls the RF generator 108 to generate a power level 2 of the RF signal 144, or a combination thereof to perform a second process operation. An example of the second process operation is a recipe step 2. As an illustration, during the second process operation, a material is deposited on the substrate S or the substrate S is etched further to process the substrate S in a second manner. Also, during the time interval between the times t8 and t12, the processor system 114 controls the valve system 138 to provide a chemistry 3 of the one or more process gases via the gas supply line 140 to the gap 142, or controls the RF generator 108 to generate a power level 3 of the RF signal 144, or a combination thereof to execute a third process operation. As an illustration, during the third process operation, the substrate S is again etched. An example of the third process operation is a recipe step 3. During the time interval between the times t12 and t16, the processor system 114 controls the valve system 138 to provide a chemistry 4 of the one or more process gases via the gas supply line 140 to the gap 142, or controls the RF generator 108 to generate a power level 4 of the RF signal 144, or a combination thereof to perform a fourth process operation. An example of the fourth process operation is a recipe step 4. As an illustration, during the fourth process operation, another material is deposited on the substrate S or the substrate S is etched further. The time interval from the time t0 to the time t16 occurs during the clock cycle 1. In a similar manner, the processor system 114 controls the valve system 138 to repeat the application of the chemistries 1 through 4 and controls the RF generator 108 to generate the power levels 1 through 4 during the clock cycle 2, which includes a time interval from the time t16 to the time t32.

During the clock cycle 1, the recipe step 1 starts at the time t0 and ends at the time t4. The recipe step 2 starts at the time t4 and ends at the time t8. The recipe step 3 starts at the time t8 and ends at the time t12 and the recipe step 4 starts at the time t12 and ends at the time t16. Similarly, during the clock cycle 2, the recipe steps 1 through 4 repeat.

In one embodiment, instead of applying different chemistries during each of the time intervals t0 through t4, t4 through t8, t8 through t12, and t12 through t16, the same chemistry is applied during two or more of the time intervals. For example, the chemistry 1 is applied during the time interval from the time t0 to the time 8.

In an embodiment, instead of applying unequal power levels during each of the time intervals t0 through t4, t4 through t8, t8 through t12, and t12 through t16, equal power levels are applied during two or more of the time intervals. For example, the power level 1 is applied during the time interval from the time t0 to the time t8.

FIG. 3 is an embodiment of a graph 300 to illustrate that a magnitude or a polarity or a duration or a combination thereof of a current signal 302 is modified periodically. The current signal 302 is an example of the current signal 152 (FIG. 1). The graph 300 plots the current signal 302 on a y-axis and the time t on an x-axis. The current signal 302 ranges from a current value −Id to a current value I4. For example, the current value −Id of the current signal 302 is less than the current value −Ic of the current signal 302, the current value −Ic is less than the current value −Ib of the current signal 302, and the current value −Ib is less than the current value −Ia of the current signal 302. The current value −Ia is less than a current value of 0 of the current signal 302. Further, in the example, the magnitude 0 of the current signal 302 is less than a magnitude of the current value I1 of the current signal 302, the magnitude of the current value I1 is less than a magnitude of the current value I2 of the current signal 302, and the magnitude of the current value I2 is less than a magnitude of the current value I3 of the current signal 302. The magnitude of the current value I3 is less than the magnitude of the current value 14 of the current signal 302.

Each current value, described herein, has a magnitude, a polarity, and a duration. For example, the current value −Id has a magnitude of Id, the current value −Ic has a magnitude of Ic, the current value −Ib has a magnitude of Ib, and the current value −Ia has a magnitude of Ia. Also, in the example, the current values −Ia through −Id have the negative polarity. To illustrate, the current values −Ia through −Id are represented as negative values. In the example, the current values I1 through I4 have a positive polarity. To illustrate, the current values I1 through 14 are positive values. As another illustration, a portion of the current signal 302 having any of the current values greater than zero flows in a direction opposite to a direction in which a portion of the current signal 302 having any of the current values less than zero flows. To further illustrate, a portion of the current signal 302 having any of the positive current values flows from the terminal 102A (FIG. 1) to the terminal 102B (FIG. 1) and a portion of the current signal 302 having any of the negative current values flows from the terminal 102B to the positive terminal 102A. Further, in the example, the current value −Id has a duration that includes a time period from the time t0 to a time t2.5, the current value −Ib has a duration that includes a time period from the time t2.5 to the time t5, the current value I4 has a duration that includes a time period from the time t5 to a time t7.5, and the current value I2 has a duration that includes a time period from the time t7.5 to the time t10. The time t2.5 is between the times t2 and t3 and the time t7.5 is between the times t7 and t8.

Independent of start or end of each process operation illustrated in FIG. 2, the processor system 114 (FIG. 1) controls the DC power source 106 to modify a magnitude or polarity or a duration or a combination thereof of the current signal 302 at predetermined time intervals, such as in a periodic manner or periodically or repeatedly, to output the current values −Id, −Ib, I2, and I4 in a pulsed manner. For example, the current signal 302 has the current value −Id from the time t0 to the time t2.5. The current signal 302 then transitions at the time t2.5 from the current value −Id to the current value −Ib and remains at the current value −Ib from the time t2.5 to the time t5. Moreover, the current signal 302 transitions at the time t5 from the current value −Ib to the current value I2 and remains at the current value I2 from the time t5 to a time t7.5. At the time t5, the processor system 114 controls the DC power source 116 to modify a polarity of the current signal 302 from negative to positive and to modify the magnitude of the current signal 302 magnitude from Ib to I2. At the time t7.5, the current signal 302 transitions from the current value I2 to the current value I4 and remains at the current value I4 from the time t7.5 to the time t10. The time period between the times t0 and t2.5 is equal to the time period between the times t2.5 and the time t5, the time period between the times t5 and t7.5, and the time period between the times t7.5 and t10 to modify the magnitude of the current signal 302 at each predetermined time interval.

Similarly, during a time period between the times t10 and t20, independent of the clock cycle of the clock signal, the processor system 114 controls the DC power source 106 to modify a magnitude or polarity or a duration or a combination thereof of the current signal 302 in the same manner in which the magnitude or polarity or duration or a combination thereof of the current signal 302 is modified between the times t0 and t10 to control the DC power source 106 repeatedly. As an example, the time period between the times t0 and t10 and the time period between the times t10 and t20 is sometimes referred to herein as a repeated time period. It should be noted that each magnitude −Id, −Ib, I2 and I4 of the current signal 302 is represented as a horizontal level and a transition between any two adjacent one of the magnitudes −Id, −Ib, I2 and I4 is represented in a vertical direction. As an example, each horizontal level, described herein, has a slope of zero and the vertical direction has a slope of infinity.

In one embodiment, during each repeated time period, one or more of the current values of the current signal 302, illustrated in FIG. 3, has one or more durations different than one or more remaining durations of one or more of remaining of the current values of the current signal 302. For example, the processor system 114 controls the DC power source 106 to have the current value −Id for a greater or a lesser time period than the time period for which the DC power source 106 is controlled to have the current value −Ib. It should be noted that a sum of durations of the current values −Id, −Ib, I2 and I4 equals 100 percent of each repeated time period.

In one embodiment, during each repeated time period, one or more of the magnitudes of the current values of the current signal 302 illustrated in FIG. 3 is different than, such as greater than or less than, one or more of remaining of the magnitudes of the current signal 302. For example, during the time period between the times t0 and t2.5, the current signal 302 has the magnitude Ia and the negative polarity instead of the magnitude Id and the negative polarity.

In an embodiment, during each repeated time period, one or more of the current values of the current signal 302 illustrated in FIG. 3 has a different polarity than one or more polarities of one or more of remaining ones of the current values of the current signal 302. For example, during the time period between the times t0 and t2.5, the current signal 302 has the magnitude 14 and the positive polarity instead of the magnitude Id and the negative polarity.

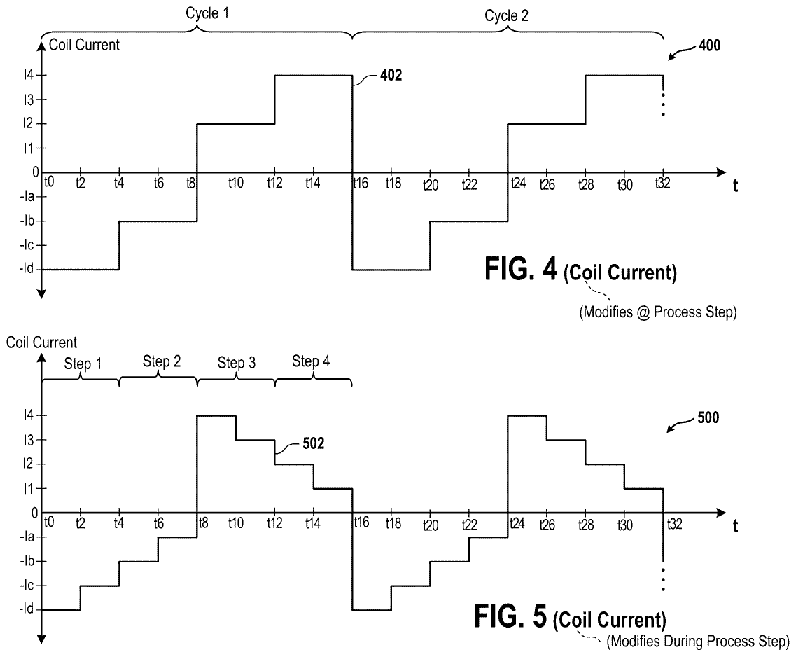

FIG. 4 is an embodiment of a graph 400 to illustrate that a magnitude or polarity or a duration or a combination thereof of a current signal 402 is modified at an end or a beginning of each process operation. The current signal 402 is an example of the current signal 152 (FIG. 1). The graph 400 plots current values of the current signal 402 on a y-axis and the time t on an x-axis.

During the clock cycle 1, the processor system 114 (FIG. 1) controls the DC power source 106 to modify a magnitude or polarity or a duration or a combination thereof of the current signal 402 at an end of each process operation to output the current values −d, −Ib, I2, and I4 in a pulsed manner. For example, the current signal 402 has the current value −Id from the time t0 to the time t4, at which the process step 1 (FIG. 2) completes and the process step 2 (FIG. 2) begins. The current signal 402 then transitions at the time t4 from the current value −Id to the current value −Ib and remains at the current value −Ib from the time t4 to the time t8, at which the process step 2 completes and the process step 3 (FIG. 2) begins. The current signal 402 transitions at the time t8 from the current value −Ib to the current value I2, also transitions from the negative polarity to the positive polarity at the time t8, and remains at the magnitude I2 from the time t8 to the time t12. At the time t8, the processor system 114 controls the DC power source 116 to modify a polarity of the current signal 402 from negative to positive. At the time t12, the process step 3 completes and the process step 4 (FIG. 2) begins. Moreover, the current signal 402 transitions at the time t12 from the current value I2 to the current value I4 and remains at the current value I4 from the time t12 to the time t16. At the time t16, the process step 4 completes and the process step 1 begins for the clock cycle 2. During the cycle 2, the processor system 114 controls the DC power source 106 to modify a magnitude or polarity or a duration or a combination thereof of the current signal 402 in the same manner in which the magnitude or polarity or duration a combination thereof of the current signal 402 is modified during the cycle 1. It should be noted that each magnitude −Id, −Ib, I2 and I4 of the current signal 402 is represented as a horizontal level and a transition between any two adjacent one of the magnitudes −Id, −Ib, I2 and I4 is represented in the vertical direction.

In one embodiment, during each clock cycle of the clock signal, one or more of the current values of the current signal 402 illustrated in FIG. 4 has one or more different durations than one or more remaining durations of one or more of remaining of the current values of the current signal 402. For example, the processor system 114 controls the DC power source 106 to have the current value −Id for a greater or a lesser time period than the time period for which the DC power source 106 is controlled to have the current value −Ib. It should be noted that a sum of durations of the current values −Id, −Ib, I2 and I4 equals 100 percent of a time period of each of the clock cycles 1 and 2.

In an embodiment, during each clock cycle of the clock signal, one or more of the magnitudes of the current values of the current signal 402 illustrated in FIG. 4 is different than, such as greater than or less than, one or more of remaining of the magnitudes of the current signal 402. For example, during the time period between the times t0 and t4, the current signal 402 has the magnitude Ia and the negative polarity instead of the magnitude Id and the negative polarity.

In one embodiment, during each cycle of the clock signal, one or more of the current values of the current signal 402 illustrated in FIG. 4 has a different polarity than one or more polarities of remaining one or more of the current values of the current signal 402. For example, during the time period between the times t0 and t4, the current signal 402 has the magnitude I4 with the positive polarity instead of the magnitude Id with the negative polarity.

FIG. 5 is an embodiment of a graph 500 to illustrate that a magnitude or polarity or a duration or a combination thereof of a current signal 502 is modified during each process operation. The current signal 502 is an example of the current signal 152 (FIG. 1). The graph 500 plots current values of the current signal 502 on a y-axis and the time t on an x-axis.

During the clock cycle 1, the processor system 114 (FIG. 1) controls the DC power source 106 to modify a magnitude or polarity or a duration or a combination thereof of the current signal 502 during each process operation to output the current values −Id, −Ic, −Ib, −Ia, I4, I3, I2 and I1 in a pulsed manner. For example, the current signal 502 has the current value −Id from the time t0 to the time t2. At the time t2, the process step 1 (FIG. 2) is ongoing. The current signal 502 then transitions at the time t2 from the current value −Id to the current value −Ic and remains at the current value −Ic from the time t2 to the time t4. The current signal 502 transitions at the time t4 from the current value −Ic to the current value −Ib, and remains at the current value −Ib from the time t4 to the time t6. At the time t6, the process step 2 (FIG. 2) is ongoing. Moreover, the current signal 502 transitions at the time t6 from the current value −Ib to the current value −Ia and remains at the current value −Ia from the time t6 to the time t8. At the time t8, the processor system 114 controls the DC power source 116 to modify a polarity of the current signal 502 from negative to positive and to transition the magnitude from Ia to I4.

The current signal 502 remains at the current value I4 from the time t8 to the time t10, and transitions at the time t10 from the current value I4 to the current value I3. At the time t10, the process step 3 is ongoing. Then, the current signal 502 remains at the current value I3 from the time t10 to the time t12, and transitions at the time t12 from the current value I3 to the current value I2. The current signal 502 remains at the current value I2 from the time t12 to the time t14, and transitions at the time t14 from the current value I2 to the current value I1. At the time t14, the process step 4 is ongoing. The current signal 502 remains at the current value I1 from the time t14 to the time t16, and transitions at the time t16 from the current value I1 to the current value −Id. At the time t16, the processor system 114 controls the DC power source 116 to modify a polarity of the current signal 502 from positive to negative. During the cycle 2, the processor system 114 controls the DC power source 106 to modify a magnitude or polarity or a duration or combination thereof of the current signal 502 in the same manner in which the magnitude or polarity or a combination thereof of the current signal 502 is modified during the cycle 1. It should be noted that each magnitude −Id, −Ic, −Ib, −Ia, I4, I3, I2 and I1 of the current signal 502 is represented as a horizontal level and a transition between any two adjacent one of the magnitudes −Id, −Ic, −Ib, −Ia, I4, I3, I2 and I1 is represented in the vertical direction.

In one embodiment, during each clock cycle of the clock signal, one or more of the current values of the current signal 502 illustrated in FIG. 5 has one or more different durations than one or more remaining durations of one or more of remaining of the current values of the current signal 502. For example, the processor system 114 controls the DC power source 106 to have the current value −Id for a greater or a lesser time period than the time period for which the DC power source 106 is controlled to have the current value −Ic. It should be noted that a sum of durations of the current values −Id, −Ic, −Ib, −Ia, I4, I3, I2 and I1 equals 100 percent of the time period of each of the clock cycles 1 and 2.

In one embodiment, during each clock cycle of the clock signal, one or more of the magnitudes of the current signal 502 illustrated in FIG. 5 is different than, such as greater than or less than, one or more of remaining of the magnitudes of the current signal 502. For example, during the time period between the times t0 and t2, the current signal 502 has the magnitude Ia and the negative polarity instead of the magnitude Id and the negative polarity.

In an embodiment, during each cycle of the clock signal, one or more of the magnitudes of the current signal 502 illustrated in FIG. 5 has a different polarity than one or more remaining polarities of one or more of remaining of the magnitudes of the current signal 502. For example, during the time period between the times t0 and t2, the current signal 502 has the magnitude I4 instead of the magnitude Id and has the positive polarity instead of the negative polarity.

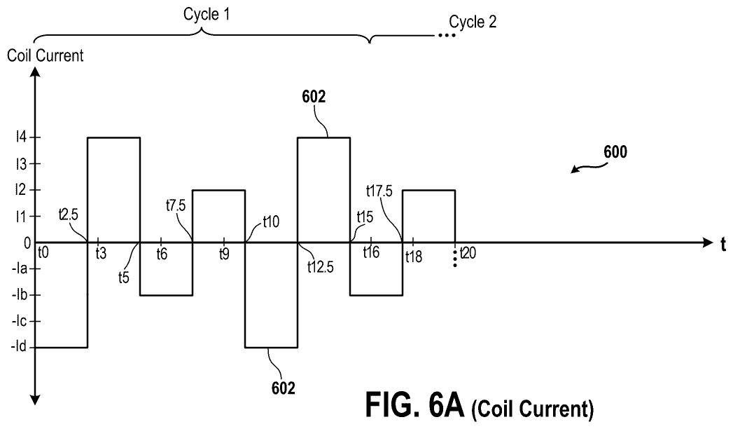

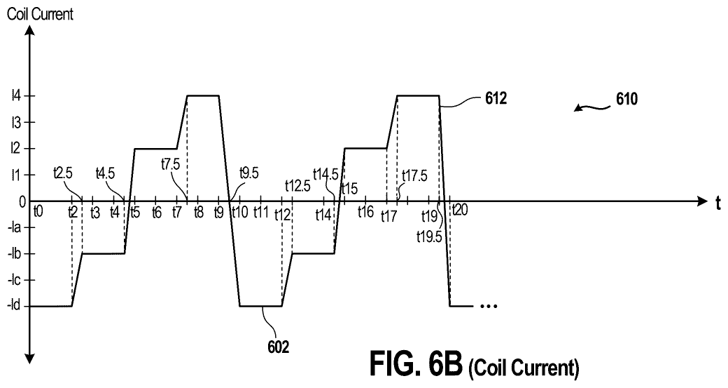

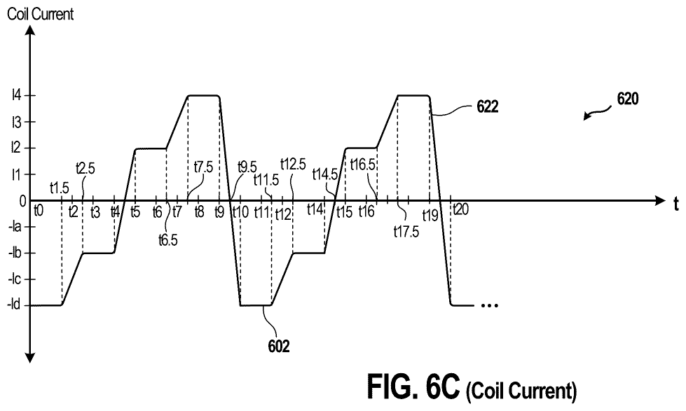

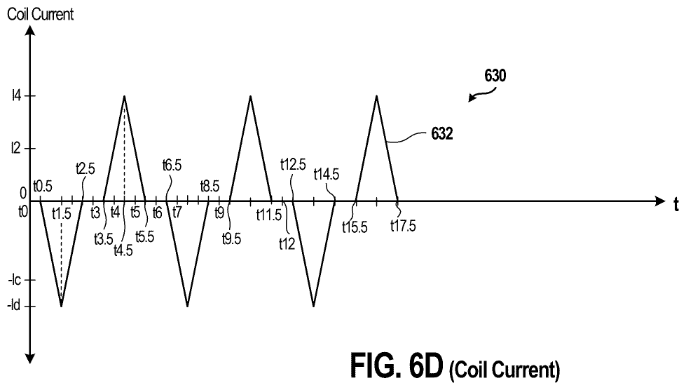

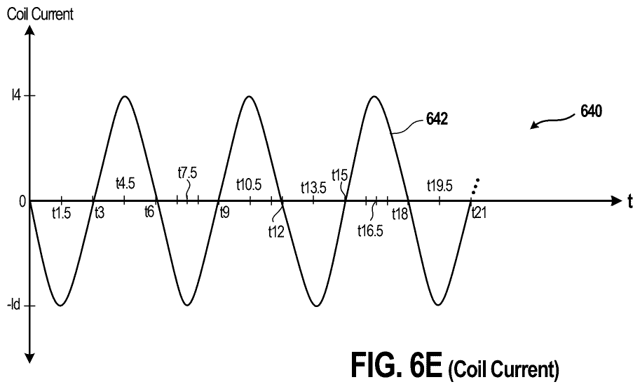

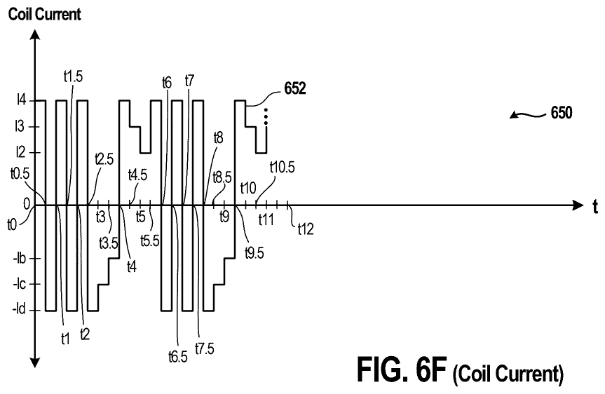

FIG. 6A is an embodiment of a graph 600 to illustrate another manner in which a magnitude or a polarity or a duration or a combination thereof of a current signal 602 is modified periodically. The current signal 602 is an example of the current signal 152 (FIG. 1). The graph 600 plots the current signal 602 on a y-axis and the time t on an x-axis.

Independent of start or end of each process operation illustrated in FIG. 2, the processor system 114 (FIG. 1) controls the DC power source 106 to modify a magnitude or polarity or a duration or a combination thereof of the current signal 602 at predetermined time intervals, such as in a periodic manner or periodically or repeatedly, to output the current values −Id, I4, −Ib, and I2 in a pulsed manner. For example, the current signal 602 has the current value −Id from the time t0 to the time t2.5. The current signal 602 then transitions at the time t2.5 from the current value −Id to the current value I4 and remains at the current value I4 from the time t2.5 to the time t5. The current signal 602 transitions at the time t5 from the current value I4 to the current value −Ib and remains at the current value −Ib from the time t5 to the time t7.5. Moreover, the current signal 602 transitions at the time t7.5 from the current value −Ib to the current value I2 and remains at the current value I2 from the time t7.5 to a time t10. At the time t10, the processor system 114 controls the DC power source 116 to modify a polarity of the current signal 602 from positive to negative and to modify the magnitude of the current signal 602 from I2 to Id. Similarly, during a time period between the times t10 and t20, independent of the clock cycle of the clock signal, the processor system 114 controls the DC power source 106 to modify a magnitude or polarity or a duration or combination thereof of the current signal 602 in the same manner in which the magnitude or polarity or duration or a combination thereof of the current signal 602 is modified between the times t0 and t10 to control the DC power source 106 repeatedly at each repeated time period. It should be noted that each magnitude −Id, I4, −Ib and I2 of the current signal 602 is represented as a horizontal level and a transition between any two adjacent one of the magnitudes −Id, I4, −Ib and I2 is represented in the vertical direction.

In one embodiment, during each repeated time period, one or more of the current values of the current signal 602 illustrated in FIG. 6A has one or more different durations than one or more remaining durations of one or more of remaining of the current values of the current signal 602. For example, the processor system 114 controls the DC power source 106 to have the current value −Id for a greater or a lesser time period than the time period for which the DC power source 106 is controlled to have the current value I4. It should be noted that a sum of durations of the current values −Id, I4, −Ib and I2 equals 100 percent of each repeated time period.

In one embodiment, during each repeated time period, one or more of the magnitudes of the current values of the current signal 602 illustrated in FIG. 6A is different than, such as greater than or less than, one or more of remaining of the magnitudes of the current signal 602. For example, during the time period between the times t0 and t2.5, the current signal 602 has the magnitude Ia and the negative polarity instead of the magnitude Id and the negative polarity.

In an embodiment, during each repeated time period, one or more of the current values of the current signal 602 illustrated in FIG. 6A has a different polarity than one or more remaining polarities of one or more of remaining of the current values of the current signal 602. For example, during the time period between the times t0 and t2.5, the current signal 602 has the magnitude 13 and the positive polarity instead of the magnitude Id and the negative polarity.

In an embodiment, during each clock cycle of the clock signal, one or more of the current values of the current signal 602 has one or more different durations than illustrated in FIG. 6A to coincide each of the different durations with a corresponding one of the process operations of FIG. 2. For example, the processor system 114 controls the DC power source 106 to have the current value −Id for the time period from the time t0 to the time t4, to have the current value I4 from the time t4 to the time t8, to have the current value −Ib from the time t8 to the time t12, and to have the current value I2 from the time t12 to the time t16. In the example, the processor system 114 controls the DC power source 106 to have the current values −Id, I4, −Ib and I2 during each additional cycle, such as the cycle 2, of the clock signal in the same manner in which the processor system 114 controls the DC power source 106 to have the current values −Id, I4, −Ib and I2 during the cycle 1. It should be noted that a sum of durations of the current values −Id, I4, −Ib and I2 equals 100 percent of the time period of each clock cycle of the clock signal.

In one embodiment, during each clock cycle of the clock signal, one or more of the current values of the current signal 602 has one or more different durations than illustrated in FIG. 6A to achieve the different durations during each process operation. For example, the processor system 114 controls the DC power source 106 to have the current value −Id for the time period from the time t0 to the time t2, to have the current value I4 from the time t2 to the time t4, to have the current value −Ib from the time t4 to the time t6, and to have the current value I2 from the time t6 to the time t8. Further, in the example, the processor system 114 controls the DC power source 106 to have the current value −Id for the time period from the time t8 to the time t10, to have the current value I4 from the time t10 to the time t12, to have the current value −Ib from the time t12 to the time t614, and to have the current value I2 from the time t14 to the time t16. In the example, the processor system 114 controls the DC power source 106 to have the current values −Id, I4, −Ib and I2 during each additional cycle, such as the cycle 2, of the clock signal in the same manner in which the processor system 114 controls the DC power source 106 to have the current values −Id, I4, −Ib and I2during the cycle 1. It should be noted that a sum of durations of the current values −Id, I4, −Ib and I2 equals 100 percent of the time period of each clock cycle of the clock signal.

FIG. 6B is an embodiment of a graph 610 to illustrate another manner in which a magnitude or a polarity or a duration or a combination thereof of a current signal 612 is modified periodically. There is a straight and sloped transition between two adjacent polarities or two adjacent magnitudes of the current signal 612. The current signal 612 is an example of the current signal 152 (FIG. 1). The graph 610 plots the current signal 612 on a y-axis and the time t on an x-axis.

Independent of start or end of each process operation illustrated in FIG. 2, the processor system 114 (FIG. 1) controls the DC power source 106 to modify a magnitude or polarity or duration or a combination thereof of the current signal 612 at predetermined time intervals, such as in a periodic manner or periodically, to output the current values −Id, −Ib, I2, and I4 in a pulsed manner. For example, the current signal 612 has the current value −Id from the time t0 to the time t2. The current signal 612 then transitions during a time period from the time 2 to the time t2.5 from the current value −Id to the current value −Ib and remains at the current value −Ib from the time t2.5 to a time t4.5, which is between the times t4 and t5. The current signal 612 transitions during a time period from the time t4.5 to the time t5 from the current value −Ib to the current value I2 and remains at the current value I2 from the time t5 to the time t7. Moreover, the current signal 612 transitions during a time period from the time t7 to the time t7.5 from the current value I2 to the current value I4 and remains at the current value I4 from the time t7.5 to a time t9.5, which is between the times t9 and t10. During a time period between the times t9.5 and t10, the processor system 114 controls the DC power source 116 to modify a polarity of the current signal 612 from positive to negative and to modify the magnitude of the current signal 612 from I4 to Id. Similarly, during a time period between the times t10 and t20, independent of the clock cycle of the clock signal, the processor system 114 controls the DC power source 106 to modify a magnitude or polarity or a combination thereof of the current signal 612 in the same manner in which the magnitude or polarity or a combination thereof of the current signal 612 is modified between the times t0 and t10 to control the DC power source 106 repeatedly at each predetermined time interval.

It should be noted that each sloped transition from one current value to a next, such as an immediately following, current value of the current signal 612 is a straight line and has a positive slope or a negative slope. For example, the sloped transition between the current values −Id and −Ib from the time t2 to the time t2.5 has a positive slope and the sloped transition between the current values I4 and −Id from the time t9.5 to the time t10 has a negative slope. It should be noted that each magnitude −Id, −Ib, I2, and I4 of the current signal 702 is represented as a horizontal level.

In one embodiment, during each repeated time period, one or more of the current values of the current signal 612 illustrated in FIG. 6B has one or more different durations than one or more remaining durations of one or more of remaining of the current values of the current signal 612. For example, the processor system 114 controls the DC power source 106 to have the current value −Id for a greater or a lesser time period than the time period for which the DC power source 106 is controlled to have the current value I4. In the example, the processor system 114 controls the DC power source 106 to have the current value −Id for the greater or the lesser time period to modify the time period of transition from the current value −Id to the current value −Ib. In the example, the duration of the current value −Id includes the greater or the lesser time period and the modified time period of transition. As another example, the processor system 114 controls the DC power source 106 to modify the time period of transition from the current value −Id to the current value −Ib. The time period of transition is modified to modify a time period for which the current value −Id is maintained. In the example, the duration of the current value −Id includes the modified time period and the modified time period of transition. As yet another example, the processor system 114 controls the DC power source 106 to have the current value I4 during the cycle 1 for a greater or a lesser time period than the time period for which the DC power source 106 is controlled to have the current value −Id during the cycle 2. In the example, the processor system 114 controls the DC power source 106 to have the current value I4 for the greater or the lesser time period to modify the time period of transition from the current value I4 during the cycle 1 to the current value −Id during the cycle 2. In the example, the duration of the current value I4 includes the greater or the lesser time period and the modified time period of transition. As still another example, the processor system 114 controls the DC power source 106 to modify the time period of transition from the current value I4 during the cycle 1 to the current value −Id during the cycle 2. The time period of transition is modified to modify a time period for which the current value I4 is maintained during the cycle 1. In the example, the duration of the current value I4 includes the modified time period and the modified time period of transition. It should be noted that a sum of durations of the current values −Id, −Ib, I2, and I4 equals 100 percent of each repeated time period.

In one embodiment, during each repeated time period, one or more of the magnitudes of the current values of the current signal 612 illustrated in FIG. 6B is different than, such as greater than or less than, one or more of remaining of the magnitudes of the current signal 612. For example, during the time period between the times t0 and t2, the current signal 612 has the magnitude Ia and the negative polarity instead of the magnitude Id and the negative polarity.

In an embodiment, during each repeated time period, one or more of the current values of the current signal 612 illustrated in FIG. 6 has a different polarity than one or more remaining polarities of one or more of remaining of the current values of the current signal 612. For example, during the time period between the times t0 and t2, the current signal 612 has the magnitude 13 and the positive polarity instead of the magnitude Id and the negative polarity.

In an embodiment, during each clock cycle of the clock signal, one or more of the current values of the current signal 612 has one or more different durations than illustrated in FIG. 6B to coincide each of the different durations with a corresponding one of the process operations of FIG. 2. For example, the processor system 114 controls the DC power source 106 to have the current value −Id for the time period from the time t0 to a time t3.5, to have the transition between the current values −Id to −Ib from the time t3.5 to the time t4, to have the current value −Ib from the time t4 to the time t7.5, to have the transition between the current values −Ib to I2 from the time t7.5 to the time t8, to have the current value I2 from the time t8 to a time t11.5, to have the transition between the current values I2 and I4 from the time t11.5 to the time t12, to have the current value I4 from the time t12 to a time t15.5, and to have a transition between the current values 14 and −Id from the time t15.5 to the time t16. The time t3.5 is between the times t3 and t4, the time t11.5 is between the times t11 and t12, and the time t15.5 is between the times t15 and t16. In the example, the processor system 114 controls the DC power source 106 to have the current values −Id, I4, −Ib and I2 during each additional cycle, such as the cycle 2, of the clock signal in the same manner in which the processor system 114 controls the DC power source 106 to have the current values −Id, I4, −Ib and I2 during the cycle 1. It should be noted that a sum of durations of the current values −Id, I4, −Ib and I2 equals 100 percent of the time period of each clock cycle of the clock signal.

In one embodiment, during each clock cycle of the clock signal, one or more of the current values of the current signal 612 has one or more different durations than illustrated in FIG. 6B to achieve the different durations during each process operation. For example, the processor system 114 controls the DC power source 106 to have the current value −Id for the time period from the time t0 to the time t1.5, to transition from the current value −Id to the current value −Ic during a time period from the time t1.5 to the time t2, to have the current value −Ic from the time t2 to the time 3.5, to transition from the current value −Ic to the current value −Ib during a time period from the time t3.5 to the time t4, to have the current value −Ib from the time t4 to a time t5.5, to transition from the current value −Ib to the current value −Ia during a time period from the time t5.5 to the time t6, to have the current value −Ia from the time t6 to the time t7.5, to transition from the current value −Ia to the current value I4 during a time period from the time t7.5 to the time t8. The time t1.5 is between the times t1 and t2, and the time t5.5 is between the times t5 and t6. Also, in the example, the processor system 114 controls the DC power source 106 to have the current value I4 from the time t8 to the time t9.5, to transition from the current value I4 to the current value I3 during a time period from the time t9.5 to the time t10, to have the current value I3 from the time t10 to the time t11.5, to transition from the current value I3 to the current value I2 during a time period from the time t11.5 to the time t12, to have the current value I2 from the time t12 to the time t13.5, to transition from the current value I2 to the current value I1 during a time period from the time t13.5 to the time t14, to have the current value I1 from the time t14 to the time t15.5, and to transition from the current value I1 to the current value −Id during a time period from the time t15.5 to the time t16. In the example, the processor system 114 controls the DC power source 106 to have the current values −Id, −Ic, −Ib, −Ia, I4, I3, I2, and I1 during each additional cycle, such as the cycle 2, of the clock signal in the same manner in which the processor system 114 controls the DC power source 106 to have the current values −Id, −Ic, −Ib, −Ia, I4, I3, I2, and I1 during the cycle 1. It should be noted that a sum of durations of the current values −Id, −Ic, −Ib, −Ia, 14, 13, 12, and I1 equals 100 percent of the time period each clock cycle of the clock signal.

FIG. 6C is an embodiment of a graph 620 to illustrate another manner in which a magnitude or a polarity or a duration or a combination thereof of a current signal 622 is modified periodically. There is a curved transition between two adjacent polarities or two adjacent magnitudes of the current signal 622. The current signal 622 is an example of the current signal 152 (FIG. 1). Instead of the straight line transitions illustrated in the graph 610, transitions of the current signal 622 are curved and sloped.

The graph 620 plots the current signal 622 on a y-axis and the time t on an x-axis. Independent of start or end of each process operation illustrated in FIG. 2, the processor system 114 (FIG. 1) controls the DC power source 106 to modify a magnitude or polarity or duration or a combination thereof of the current signal 622 at predetermined time intervals, such as in a periodic manner or periodically, to output the current values −Id, −Ib, I2, and I4 in a pulsed manner. For example, the current signal 622 has the current value −Id from the time t0 to the time t1.5. The current signal 622 then transitions during a time period from the time 1.5 to the time t2.5 from the current value −Id to the current value −Ib and remains at the current value −Ib from the time t2.5 to a time t4. The current signal 622 transitions during a time period from the time t4 to the time t5 from the current value −Ib to the current value I2 and remains at the current value I2 from the time t5 to the time t6.5. Moreover, the current signal 622 transitions during a time period from the time t6.5 to the time t7.5from the current value I2 to the current value I4 and remains at the current value I4 from the time t7.5 to the time t9. During a time period from the time t9 to the time t10, the processor system 114 controls the DC power source 116 to modify a polarity of the current signal 622 from positive to negative and to modify the magnitude of the current signal 622 from I4 to Id. Similarly, during a time period between the times t10 and t20, independent of the clock cycle of the clock signal, the processor system 114 controls the DC power source 106 to modify a magnitude or polarity or duration or a combination thereof of the current signal 622 in the same manner in which the magnitude or polarity or duration or a combination thereof of the current signal 622 is modified between the times t0 and t10 to control the DC power source 106 repeatedly at each predetermined time interval.

It should be noted that each sloped transition from one current value to a next current value of the current signal 622 is a curved line and has a positive slope or a negative slope. For example, the sloped transition between the current values −Id and −Ib from the time t1.5 to the time t2.5 has a positive slope and the sloped transition between the current values I4 and −Id from the time t9 to the time t10 has a negative slope.

In one embodiment, during each repeated time period, one or more of the current values of the current signal 622 illustrated in FIG. 6C has one or more different durations than one or more remaining durations of one or more of remaining of the current values of the current signal 622 in the same manner in which the one or more of the current values of the current signal 612 illustrated in FIG. 6B has the one or more different durations.

In one embodiment, during each repeated time period, one or more magnitudes of one or more of the current values of the current signal 622 illustrated in FIG. 6C is different than, such as greater than or less than, one or more of remaining of the magnitudes of the current signal 622. For example, during the time period between the times t0 and t1.5, the current signal 622 has the magnitude Ia and the negative polarity instead of the magnitude Id and the negative polarity.

In an embodiment, during each repeated time period, one or more of the current values of the current signal 622 illustrated in FIG. 6C has a different polarity than one or more remaining polarities of one or more of remaining of the current values of the current signal 622. For example, during the time period between the times t0 and t1.5, the current signal 622 has the magnitude I3 and the positive polarity instead of the magnitude Id and the negative polarity.

In an embodiment, during each clock cycle of the clock signal, one or more of the current values of the current signal 622 has one or more different durations than illustrated in FIG. 6C to coincide each of the different durations with a corresponding one of the process operations of FIG. 2. The same example described above with reference to FIG. 6B applies here.

In one embodiment, during each clock cycle of the clock signal, one or more of the current values of the current signal 622 has one or more different durations than illustrated in FIG. 6C to achieve the different durations during each process operation. The same example described above with reference to FIG. 6B applies here.

FIG. 6D is an embodiment of a graph 630 to illustrate another manner in which a magnitude or a polarity or a duration or a combination thereof of a current signal 632 is modified periodically. The current signal 632 has multiple triangular and inverted triangular shapes. The current signal 632 is an example of the current signal 152 (FIG. 1). The graph 630 plots the current signal 632 on a y-axis and the time t on an x-axis.

Independent of start or end of each process operation illustrated in FIG. 2, the processor system 114 (FIG. 1) controls the DC power source 106 to modify a magnitude or polarity or duration or a combination thereof of the current signal 632 at predetermined time intervals, such as in a periodic manner or periodically, to output the current values −Id and I4 in a pulsed manner. For example, the current signal 632 has the current value of 0 from the time t0 to a time t0.5, which is between the times t0 and t1. The current signal 632 transitions from the current value of zero to the current value of −Id during a time period from the time t0.5 to the t1.5. The current signal 632 then transitions during a time period from the time t1.5 to the time t2.5 from the current value −Id to the current value of zero and remains at the current value of zero from the time t2.5 to the time t3.5. The transition from the time t0.5 to the time t1.5 has a negative slope and is straight and the transition from the time t1.5 to the time t2.5 has a positive slope and is straight.

A combination of the transition from the time t0.5 to the t1.5 and the transition from the time t1.5 to the time t2.5 forms an inverted triangular shape. The current value of −Id at the time t1.5 is a peak current value, such as having a maximum current magnitude and the negative polarity, of the inverted triangular shape extending from the time t0.5 to the time t2.5.

The current signal 632 transitions during a time period from the time t3.5 to the time t4.5 from the current value of zero to the current value I4 and transitions during a time period from the time t4.5 to the time t5.5 from the current value of I4 to the current value of zero. The transition from the time t3.5 to the time t4.5 has a positive slope and is straight, and the transition from the time t4.5 to the time t5.5 has a negative slope and is straight. The current signal 632 remains at the current value of zero from the time t5.5 to the time t6.

A combination of the transition from the time t3.5 to the t4.5 and the transition from the time t4.5 to the time t5.5 forms a triangular shape. The current value of I4 at the time t4.5 is a peak current value, such as having a maximum current magnitude and the positive polarity, of the triangular shape extending from the time t3.5 to the time t5.5.

In this manner, the current signal 632 repeats the triangular and inverted triangular shapes periodically from the time t6 to the time t12. The time period between the times t0 and t6 or between the times t6 and t12 is an example of a repeated time period.

In one embodiment, during each repeated time period, one or more of the current values of the current signal 632 illustrated in FIG. 6D has one or more different durations than one or more remaining durations of one or more of remaining of the current values of the current signal 632. For example, during each repeated time period, each inverted triangular shape of the current signal 632 is applied for a greater or a lesser amount of time than that illustrated in FIG. 6D. To illustrate, the inverted triangular shape extending from the time t0.5 to the time t2.5 extends instead from the time t0 to the time t3. As another example, during each repeated time period, each triangular shape of the current signal 632 is applied for a greater or a lesser amount of time than that illustrated in FIG. 6D. To illustrate, the triangular shape extending from the time t3.5 to the time t5.5 extends instead from the time t3 to the time t6. It should be noted that a sum of durations of the triangular shapes and inverted triangular shapes of the current signal 632 and zero current values during each repeated time period equals 100 percent of the repeated time period.

In one embodiment, during each repeated time period, one or more of the peak current values of the current signal 632 illustrated in FIG. 6D is different than, such as greater than or less than, one or more of remaining of the peak current values of the current signal 632. For example, instead of achieving the peak current value −Id at the time t1.5, the current signal 632 achieves the magnitude Ic and the negative polarity. As another example, instead of achieving the peak current value I4 at the time t4.5, the current signal 632 achieves the magnitude 12 and the positive polarity.

In an embodiment, during each repeated time period, one or more of the current values of the current signal 632 illustrated in FIG. 6D has a different polarity than one or more polarities of one or more of remaining of the current values of the current signal 632. For example, instead of achieving the peak current value −Id at the time t1.5, the peak current value of I2 is achieved at the time t1.5. The peak current value I2 is achieved by transitioning from the current value of zero at the time t0.5 to the current value I2 at the time t1.5.

In an embodiment, during each clock cycle of the clock signal, one or more of the current values of the current signal 632 has one or more different durations than that illustrated in FIG. 6D to coincide each of the different durations with a corresponding one of the process operations of FIG. 2. For example, the processor system 114 controls the DC power source 106 to transition from the current value of zero to the current value −Id during the time period from the time t0 to the time t2, to transition from the current value of −Id to the current value of zero during the time period from the time t2 to the time t4, to transition from the current value of zero to the current value of −Ic from the time t4 to the time t6, to transition from the current value of −Ic to the current value of zero from the time t6 to the time t8, to transition from the current value of zero to the current value I3 from the time t8 to the time t10, to transition from the current value of I3 to the current value of zero from the time t10 to the time t12, to transition from the current value of zero to the current value of 14 from the time t12 to the time t14, and to transition from the current value of I4 to the current value of zero from the time t14 to the time t16. In the example, the processor system 114 controls the DC power source 106 to have transition among the current values zero, −Id, −Ic, I3 and I4 during each additional cycle, such as the cycle 2, of the clock signal in the same manner in which the processor system 114 controls the DC power source 106 to transition among the current values zero, −Id, −Ic, I3 and I4 during the cycle 1. It should be noted that a sum of durations formed by the current values zero, −Id, −Ic, I3 and I4 equals 100 percent of the time period of each clock cycle of the clock signal.

In one embodiment, during each clock cycle of the clock signal, one or more of the current values of the current signal 632 has one or more different durations than that illustrated in FIG. 6D to achieve the different durations during each process operation. For example, the processor system 114 controls the DC power source 106 to transition from the current value of zero to the current value −Id during the time period from the time t0 to the time t1, to transition from the current value −Id to the current value of zero during the time period from the time t1 to the time t2, to transition from the current value of zero to the current value −Ic during the time period from the time t2 to the time t3, to transition from the current value −Ic to the current value of zero during the time period from the time t3 to the time t4, to transition from the current value of zero to the current value −Ib during the time period from the time t4 to the time t5, to transition from the current value −Ib to the current value of zero during the time period from the time t5 to the time t6, to transition from the current value of zero to the current value −Ia during the time period from the time t6 to the time t7, and to transition from the current value −Ia to the current value of zero during the time period from the time t7 to the time t8.

In the example, the processor system 114 controls the DC power source 106 to transition from the current value of zero to the current value I1 during the time period from the time t8 to the time t9, to transition from the current value I1 to the current value of zero during the time period from the time t9 to the time t10, to transition from the current value of zero to the current value I2 during the time period from the time t10 to the time t11, to transition from the current value I2 to the current value of zero during the time period from the time t11 to the time t11, to transition from the current value of zero to the current value I3 during the time period from the time t12 to the time t13, to transition from the current value of I3 to the current value of zero during the time period from the time t13 to the time t14, to transition from the current value of zero to the current value I4 during the time period from the time t14 to the time t15, and to transition from the current value of I4 to the current value of zero during the time period from the time t15 to the time t16.

Further, in the example, the processor system 114 controls the DC power source 106 to have the current values −Id, −Ic, −Ib, −Ia, 0, I1, I2, I3, and I4 during each additional cycle, such as the cycle 2, of the clock signal in the same manner in which the processor system 114 controls the DC power source 106 to have the current values −Id, −Ic, −Ib, −Ia, 0, I1, I2, I3, and I4 during the cycle 1. It should be noted that a sum of durations formed by the current values −Id, −Ic, −Ib, −Ia, 0, I1, I2, I3, and I4 equals 100 percent of the time period of each clock cycle of the clock signal.

In an embodiment, instead of each inverted triangular shape being an inverted isosceles triangle, an inverted right angled triangular shape is formed by the current signal 632. For example, the current signal 632 transitions at the time t0.5 from the current value of zero to the current value −Id. The current signal 632 transitions from the current value −Id to the current value of zero during a time period from the time t0.5 to the time t2.5.

Similarly, in one embodiment, instead of each triangular shape being an isosceles triangle, a right angled triangular shape is formed by the current signal 632. For example, the current signal 632 transitions at the time t3.5 from the current value of zero to the current value of I4. The coil current transitions from the current value of I4 to the current value of zero during a time period from the time t3.5 to the time t6.

FIG. 6E is an embodiment of a graph 640 to illustrate another manner in which a magnitude or a polarity or a combination thereof of a current signal 642 is modified periodically. The current signal 642 is sinusoidal. There is a curved transition between two adjacent peak current values of the current signal 642. The current signal 642 is an example of the current signal 152 (FIG. 1). The current signal 642 is the same as the current signal 632 (FIG. 6D) except that instead of the straight line transitions of the current signal 632, transitions of the current signal 642 are curved and sloped to form a sine waveform.

In one embodiment, during each repeated time period, one or more of the current values of the current signal 642 illustrated in FIG. 6D has one or more different durations than one or more remaining durations of one or more of remaining of the current values of the current signal 642 in the same manner in which the one or more of the current values of the current signal 632 illustrated in FIG. 6C has the one or more different durations.

In one embodiment, during each repeated time period, one or more of the peak current values of the current signal 642 illustrated in FIG. 6E is different than, such as greater than or less than, one or more of remaining of the peak current values of the current signal 642. For example, instead of achieving the peak current value −Id at the time t1.5, the current signal 642 achieves the magnitude Ic and the negative polarity. As another example, instead of achieving the peak current value I4 at the time t4.5, the current signal 642 achieves the magnitude I2 and the positive polarity.

In an embodiment, during each repeated time period, one or more of the current values of the current signal 642 illustrated in FIG. 6E has a different polarity than one or more remaining polarities of one or more of remaining of the current values of the current signal 642. The same example described above with reference to FIG. 6D applies here.

In an embodiment, during each clock cycle of the clock signal, one or more of the current values of the current signal 642 has one or more different durations than that illustrated in FIG. 6D to coincide each of the different durations with a corresponding one of the process operations of FIG. 2. The same example described above with reference to FIG. 6D applies here.

In one embodiment, during each clock cycle of the clock signal, one or more of the current values of the current signal 642 has one or more different durations than that illustrated in FIG. 6E to achieve the different durations during each process operation. The same example described above with reference to FIG. 6D applies here.

FIG. 6F is an embodiment of a graph 650 to illustrate yet another manner in which a magnitude or a polarity or a duration or a pattern a combination thereof of a current signal 652 is modified periodically. For example, the pattern of the coil current 652 changes at each predetermined time interval. The current signal 652 is an example of the current signal 152 (FIG. 1). The graph 650 plots the current signal 652 on a y-axis and the time t on an x-axis.

Independent of start or end of each process operation illustrated in FIG. 2, the processor system 114 (FIG. 1) controls the DC power source 106 to modify a magnitude or polarity or a duration or the pattern or a combination thereof of the current signal 652 at predetermined time intervals, such as in a periodic manner or periodically, to output the current values −Id, −Ic, −Ib, I4, I3, and I2 in a pulsed manner. The current signal 652 is output in the pulsed manner to forma multiple patterns, including a first pattern. For example, the current signal 652 transitions at the time t0 from the current value of zero to the current value I4 and remains at the current value I4 from the time t0 to the time t0.5. The current signal 652 then transitions at the time t0.5 from the current value I4 to the current value −Id and remains at the current value −Id from the time t0.5 to the time t1. The current signal 652 transitions at the time t1 from the current value −Id to the current value I4 and remains at the current value I4 during a time period from the time t1 to the time t1.5. At the time t1.5, the current signal 652 transitions from the current value I4 to the current value −Id and remains at the current value −Id from the time t1.5 to the time t2. The current signal 652 then transitions at the time t2 from the current value −Id to the current value I4 and remains at the current value I4 from the time t2 to the time t2.5. The current signal 652 transitions at the time t2.5 from the current value I4 to the current value −Id. A time period from the time t0 to the time t2.5 is an example of a predetermined time interval.

After the predetermined time interval, the processor system 114 controls the DC power source 106 to modify the first pattern of the current signal 652 formed during the time period from the time t0 to the time t2.5. The first pattern is modified to form a second pattern of the current signal 652. The second pattern is formed during a time period from the time t2.5 to the time t4. For example, during a time period from the time t2.5 to the time t3, the current signal 652 remains at the current value −Id and transitions at the time t3 from the current value −Id to the current value −Ic. Then, during a time period from the time t3 to the time t3.5, the current signal 652 remains at the current value −Ic and transitions at the time t3.5 from the current value −Ic to the current value −Ib. Thereafter, during a time period from the time t3.5 to the time t4, the current signal 652 remains at the current value −Ib and transitions at the time t4 from the current value −Ib to the current value I4. Further, during a time period from the time t4 to the time t4.5, the current signal 652 remains at the current value I4 and transitions at the time t4.5 from the current value I4 to the current value I3. Also, during a time period from the time t4.5 to the time t5, the current signal 652 remains at the current value I3 and transitions at the time t5 from the current value I3 to the current value I2. The current signal 652 remains at the current value I2 during a time period from the time t5 to the time t5.5. At the time t5.5, the current signal 652 transitions from the current value I2 to the current value I4. A time period from the time t2.5 to the time t5.5 is an example of a predetermined time interval. During a time period from the time t5.5 to the time t8, the first pattern repeats. Also, during a time period from the time t8 to the time t11, the second pattern repeats. It should be noted that each magnitude −Id, I4, −Ic, −Ib, I3, and I2 of the current signal 652 is represented as a horizontal level and a transition between any two adjacent one of the magnitudes −Id, I4, −Ic, −Ib, I3, and I2 is represented in the vertical direction In one embodiment, during each repeated time period, one or more of the current values of the current signal 652 illustrated in FIG. 6F has one or more different durations than one or more remaining durations of one or more of remaining of the current values of the current signal 652. For example, the processor system 114 controls the DC power source 106 to have the current value −Id for a greater or a lesser time period than the time period for which the DC power source 106 is controlled to have the current value I4. It should be noted that a sum of durations of the current values I4 and −Id equals 100 percent of each repeated time period.

In one embodiment, during each repeated time period, one or more of the magnitudes of the current values of the current signal 652 illustrated in FIG. 6F is different than, such as greater than or less than, one or more of remaining of the magnitudes of the current signal 652. For example, during the time period between the times t0 and t0.5, the current signal 652 has the magnitude 13 and the positive polarity instead of the magnitude 14 and the positive polarity.

In an embodiment, during each repeated time period, one or more of the current values of the current signal 652 illustrated in FIG. 6F has a different polarity than one or more remaining polarities of one or more of remaining of the current values of the current signal 652. For example, during the time period between the times t0 and t0.5, the current signal 602 has the magnitude Ic and the negative polarity instead of the magnitude I4 and the positive polarity.

In an embodiment, during each clock cycle of the clock signal, one or more of the current values of the current signal 652 has one or more different durations than illustrated in FIG. 6F to coincide each pattern of the current signal 652 with a corresponding one of the process operations of FIG. 2. For example, the processor system 114 controls the DC power source 106 to modify a duration for which the current value I4 is maintained or a duration for which the current value −Id is maintained or a combination thereof to extend the first pattern from the time t0 to the time t4. In the example, the processor system 114 controls the DC power source 106 to modify a duration for which the current value −Id is maintained or a duration for which the current value −Ic is maintained or a duration for which the current value −Ib is maintained or a duration for which the current value I4 is maintained or a duration for which the current value I3 is maintained or a duration for which the current value I2 is maintained or a combination thereof to extend the second pattern from the time t4 to the time t8. In a similar manner, the first pattern is extended during the time period from the time t8 to the time t12 and the second pattern is extended during the time period from the time t12 to the time t16 during the cycle 1. The first and second patterns are repeated in the same manner during each cycle of the clock signal as that during the cycle 1 of the clock signal. It should be noted that a sum of durations of the current values −Id, I4, −Ic, −Ib, I3, and I2 equals 100 percent of the time period of each clock cycle of the clock signal.

In one embodiment, during each clock cycle of the clock signal, one or more of the current values of the current signal 652 has one or more different durations than illustrated in FIG. 6F to achieve each pattern of the current signal 652 during each process operation. For example, the processor system 114 controls the DC power source 106 to modify a duration for which the current value I4 is maintained or a duration for which the current value −Id is maintained or a combination thereof to extend the first pattern from the time t0 to the time t2. In the example, the processor system 114 controls the DC power source 106 to modify a duration for which the current value −Id is maintained or a duration for which the current value −Ic is maintained or a duration for which the current value −Ib is maintained or a duration for which the current value I4 is maintained or a duration for which the current value I3 is maintained or a duration for which the current value I2 is maintained or a combination thereof to extend the second pattern from the time t2 to the time t4. In a similar manner, the first pattern is extended during the time period from the time t4 to the time t6 and the second pattern is extended during the time period from the time t6 to the time t8. In a similar manner, the first and second patterns are alternated from the time t8 to the time t16 during the cycle 1 of the clock signal. The first and second patterns are repeated in the same manner during each following cycle, such as the cycle 2, of the clock signal as that during the cycle 1 of the clock signal. It should be noted that a sum of durations of the current values −Id, I4, −Ic, −Ib, I3, and I2 equals 100 percent of the time period of each clock cycle of the clock signal.

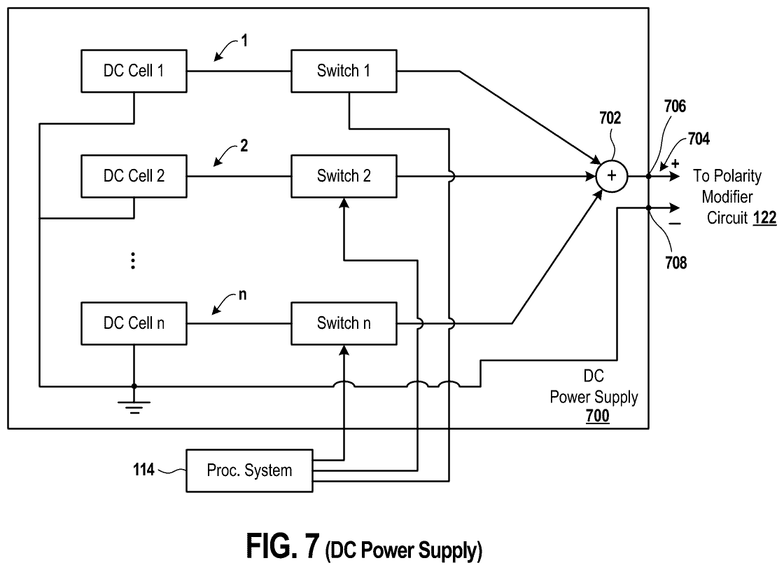

FIG. 7 is a diagram of an embodiment of a system 700 to illustrate a direct current (DC) power supply 700 for generating a current magnitude signal 704. The DC power supply 700 is an example of the DC power supply 120 (FIG. 1). The DC power supply 700 includes multiple DC cells 1 through n, where n is a positive integer. Also, the DC power supply 700 includes multiple switches 1 through n. The DC power supply 700 has an adder 702, such as a summer. An example of each DC cell is a battery. As an example, each switch, as described herein, is one or more transistors. As an example, the adder 702 is implemented as an ASIC or a PLD. The DC power supply 700 has a terminal 706 and another terminal 708. The terminal 708 is coupled to a ground potential of each of the DC cells 1 through n.

The processor system 114 is coupled to each of the switches 1 through n. Also, each DC cell is coupled to a respective switch. For example, the DC cell 1 is coupled to the switch 1, the DC cell 2 is coupled to the switch 2, and so on until the DC cell n is coupled to the switch n. The switches 1 through n are coupled to the adder 702. The adder 702 is coupled to the polarity modifier circuit 122 (FIG. 1).

To decrease an amount of current supplied from the DC power supply 700, the processor system 114 generates and sends one or more off control signals to corresponding one or more of the switches 1 through n to open the one or more of the switches 1 through n. For example, the processor system 114 generates and sends a first off control signal to the switch 1 to open the switch 1 and a second off control signal to the switch 2 to open the switch 2. The one or more off control signals are examples of the one or more control signals 148 (FIG. 1). When the one or more of the switches 1 through n are open, corresponding one or more of the DC cells 1 through n are disconnected from the adder 702. For example, when the switch 1 is open, the DC cell 1 is decoupled from the adder 702 and when the switch 2 is open, the DC cell 2 is decoupled from the adder 702. When the one or more of the switches 1 through n are open, one or more current signals 1 through n from corresponding one or more of the DC cells 1 through n coupled to the one or more of the switches 1 through n are not supplied to the adder 702. As an example, when the switches 1 and 2 are open, the current signal 1 from the DC cell 1 is not supplied to the adder 702 and the current signal 2 from the DC cell 2 is not supplied to the adder 702.

On the other hand, to increase an amount of current supplied from the DC power supply 700, the processor system 114 generates and sends one or more on control signals to corresponding one or more of the switches 1 through n to close the one or more of the switches 1 through n. For example, the processor system 114 generates and sends a first on control signal to the switch 1 to close the switch 1 and a second on control signal to the switch 2 to close the switch 2. The one or more on control signals are examples of the one or more control signals 148. When the one or more of the switches 1 through n are closed, corresponding one or more of the DC cells 1 through n are connected to the adder 702. For example, when the switch 1 is closed, the DC cell 1 is coupled to the adder 702 and when the switch 2 is closed, the DC cell 2 is coupled to the adder 702. When the one or more of the switches 1 through n are closed, the one or more current signals 1 through n from corresponding one or more of the DC cells 1 through n coupled to the one or more of the switches 1 through n are supplied to the adder 702. For example, when the switches 1 and 2 are closed, the current signal 1 from the DC cell 1 is supplied to the adder 702 and the current signal 2 from the DC cell 2 is supplied to the adder 702. The adder 702 adds one or more of the n current signals from the one or more of the n DC cells that are coupled to the adder 702 via the one or more of the switches 1 through n to output the current magnitude signal 704 from the adder 702 to the terminal 706.

By adding one or more of the n current signals, a magnitude of the current magnitude signal 704 is modified. For example, when the current signal 1 is not added by the adder 702 to the current signals 2 through n, a magnitude of the current magnitude signal 704 decreases compared to when the current signal 1 is added to the current signals 2 through n. On the other hand, when the current signal 1 is added by the adder 702 to the current signals 2 through n, a magnitude of the current magnitude signal 704 increases compared to when the current signal 1 is not added to the current signals 2 through n.

By modifying the magnitude of the current magnitude signal 704, a magnitude of the current signal 152 is modified. For example, the magnitude of the current signal 152 is maintained at a level for a time period or is transitioned to another magnitude level. The current magnitude signal 704 is sent to the polarity modifier circuit 122 via the terminal 706 for modifying a polarity of the current magnitude signal 704.

In addition, by controlling an amount of time for which a corresponding one of the switches 1 through n is closed, one or more durations of the current magnitude signal 704 are controlled. For example, the processor system 114 controls the switches 1 through n to be closed for an amount of time equal to a duration of a magnitude of the current magnitude signal 704. For example, with an increase in an amount of time for which the switches 1 through n are closed, a time interval, such as a time period, for which the current magnitude signal 704 is output at the terminal 706 increases to increase the duration of the magnitude. On the other hand, with a decrease in the amount of time for which the switches 1 through n are closed, a time interval, such as a time period, for which the current magnitude signal 704 is output at the terminal 706 decreases to decrease the duration of the magnitude.

FIG. 8 is a diagram of an embodiment of a system 800 to illustrate a polarity modifier circuit 802. The polarity modifier circuit 802 is an example of the polarity modifier circuit 122 (FIG. 1). The system 800 includes the DC power supply 700, the processor system 114, and the polarity modified circuit 802. The polarity modifier circuit 802 includes switches SW1 and SW2. The switch SW1 has a terminal T1a, a terminal T1b, and a terminal T1c. Also, the switch SW2 has a terminal T2a, a terminal T2b, and a terminal T2c.

The processor system 114 is coupled to the switches SW1 and SW2. Also, the terminal 706 is coupled to the terminal T1a and the terminal 708 is coupled to the terminal T2a. The terminal T1b is coupled to the terminal 102A of the magnetic coil 102 and the terminal T1c is coupled to the terminal 102B of the magnetic coil 102. Also, the terminal T2b is coupled to the terminal 102B and the terminal T2c is coupled to the terminal 102A.

The processor system 114 controls each of the switches SW1 and SW2 to modify a position of the switch. The position is modified to change a polarity, from positive to negative or from negative to positive, of the current magnitude signal 704 to output the current signal 152. For example, the processor system 114 sends a first position control signal to the switch SW1 and a first position control signal to the switch SW2. The first position control signals are examples of the position control signals 150 (FIG. 1). Upon receiving the first position control signal, the terminal T1a of the switch SW1 is connected to the terminal T1b. Also, upon receiving the first position control signal, the terminal T2a of the switch SW2 is connected to the terminal T2b. When the terminal T1a is coupled to the terminal T1b and the terminal T2a is coupled to the terminal T2b, the current magnitude signal 704 output from the terminal 706 is transferred via the terminal T1a to the terminal T1b as the current signal 152 having the positive polarity. The current signal 152 having the positive polarity is sent from the terminal T1b to the terminal 102A to generate the magnetic field in a first direction within the gap 142 (FIG. 1). A return current signal 804 generated as a result of the magnetic field having the first direction is transferred from the terminal 102B via the terminal T2b and the terminal T2a to the terminal 708, which is coupled to the ground potential.

Similarly, as another example, the processor system 114 sends a second position control signal to the switch SW1 and a second position control signal to the switch SW2. The second position control signals are examples of the position control signals 150. Upon receiving the second position control signal, the terminal T1a of the switch SW1 connected to the terminal T1c. Also, upon receiving the second position control signal, the terminal T2a of the switch SW2 connected to the terminal T2c. When the terminal T1a is coupled to the terminal T1c and the terminal T2a is coupled to the terminal T2c, the current magnitude signal 704 output from the terminal 706 is transferred via the terminal T1a to the terminal T1c as the current signal 152 having the negative polarity. The current signal 152 having the negative polarity is sent from the terminal T1c to the terminal 102B to generate the magnetic field in a second direction within the gap 142 (FIG. 1). The second direction is opposite to the first direction. A return current signal 806 generated as a result of the magnetic field having the second direction is transferred from the terminal 102B via the terminal T2c and the terminal T2a to the terminal 708, which is coupled to the ground potential.

In an embodiment, by modifying the polarity of the current signal 152 periodically, a symmetry in tilts can be achieved across the top surface of the substrate S. To illustrate, the tilts change direction with a change in the polarity. To further illustrate, when the polarity is positive, the tilts are upwards along the top surface and when the polarity is negative, the tilts are downwards along the top surface. As another illustration, the symmetry can be achieved with respect to an axis that passes through a center of the substrate S. As another illustration, a top half of the substrate S has tilts that are symmetric with respect to a bottom half of the substrate S. As yet another illustration, the tilts that are symmetric are radially inward or outward, with almost no dependence on azimuthal angle across the top surface of the substrate S.

As an example, a tilt of a feature of the substrate S is an angle formed between the center of the opening of the feature and the center of the bottom wall of the feature. The feature has the opening in the top plane. The feature also has the bottom wall and the side wall. The opening is spaced apart from the bottom wall by the side wall.

It should be noted that although the symmetry in tilts can be achieved, in an embodiment, a zero tilt is achieved in all features of the substrate S by controlling one or more durations of the current signal 152, or one or more magnitudes of the current signal 152, or by modifying one or more polarities of the current signal 152, or a combination thereof.

In one embodiment, the terms time period and time interval are used herein interchangeably. In an embodiment, the terms predetermined time interval and repeated time period are used herein interchangeably.

Broadly speaking, in a variety of embodiments, a controller, as used herein, is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A method for controlling tilt across a surface of a substrate, comprising:
providing a current signal to a magnetic coil associated with a plasma chamber, wherein the signal produces a magnetic field within the plasma chamber;
controlling a direct current (DC) power source to output a plurality of magnitudes of the signal in a pulsed manner during a clock cycle; and
repeating the plurality of magnitudes of the current signal with each additional clock cycle.

2. The method of claim 1, wherein said controlling the DC power source includes controlling the DC power source to modify a polarity of the current signal during the clock cycle to output the current signal having a plurality of polarities during the clock cycle, wherein said repeating includes repeating the plurality of polarities during the additional clock cycle.

3. The method of claim 1, wherein the plurality of magnitudes include a first magnitude and a second magnitude, wherein the first magnitude is output during a first time interval and the second magnitude is output during a second time interval, wherein the first magnitude transitions to the second magnitude to output the plurality of magnitudes in the pulsed manner.

4. The method of claim 3, wherein said controlling the DC power source includes controlling a transition from the first magnitude to the second magnitude to have a straight slope to output the plurality of magnitudes in the pulsed manner, wherein the straight slope is a positive slope or a negative slope.

5. The method of claim 3, wherein said controlling the DC power source includes controlling a transition from the first magnitude to the second magnitude to have a curved slope to output the plurality of magnitudes in the pulsed manner, wherein the curved slope is a positive slope or a negative slope.

6. The method of claim 3, wherein the plurality of polarities include a first polarity and a second polarity, wherein said controlling the DC power source includes controlling the DC power source to have the first polarity during the first time interval in which the current signal has the first magnitude and have the second polarity during the second time interval in which the current signal has the second magnitude.

7. The method of claim 6, wherein said controlling the DC power source includes controlling a transition from the first polarity to the second polarity to have a straight slope to output the plurality of magnitudes in the pulsed manner, wherein the straight slope is a positive slope or a negative slope.

8. The method of claim 6, wherein said controlling the DC power source includes controlling a transition from the first polarity to the second polarity to have a curved slope to output the plurality of magnitudes in the pulsed manner, wherein the curved slope is a positive slope or a negative slope.

9. The method of claim 1, wherein the plurality of magnitudes are output during a time period of a process operation, wherein during the process operation, a substrate is processed using a chemistry and a power level.

10. The method of claim 1, wherein the plurality of magnitudes are output at a beginning of a first process operation, wherein during the first process operation, a substrate is processed using a first chemistry and a first power level, wherein said repeating the plurality of magnitudes occurs at a beginning of a second process operation, wherein during the second process operation, the substrate is processed using a second chemistry and a second power level.

11. The method of claim 1, wherein the plasma chamber is a capacitively coupled plasma chamber, wherein the a capacitively coupled plasma chamber includes an upper electrode and a substrate support, wherein the upper electrode is located above the substrate support, wherein the magnetic coil is located above the upper electrode.

12. The method of claim 11, wherein the magnetic coil is thicker than a transformer coupled plasma (TCP) coil.

13. A method for controlling tilt across a surface of a substrate, comprising:
providing a current signal to a magnetic coil associated with a plasma chamber, wherein the signal produces a magnetic field within the plasma chamber;
controlling a direct current (DC) power source to output a plurality of magnitudes of the signal in a pulsed manner during a clock cycle, wherein the plurality of magnitudes are at a beginning of a process operation; and
repeating the plurality of magnitudes of the current signal at a beginning of each additional process operation.

14. The method of claim 13, wherein said controlling the DC power source includes controlling the DC power source to modify a polarity of the current signal at an end of the process operation and at the beginning of the additional process operation to output the current signal having a plurality of polarities during the clock cycle.

15. The method of claim 13, wherein the plurality of magnitudes include a first magnitude and a second magnitude, wherein the first magnitude is output during a first time interval and the second magnitude is output during a second time interval, wherein the first magnitude transitions to the second magnitude to output the plurality of magnitudes in the pulsed manner.

16. The method of claim 15, wherein said controlling the DC power source includes controlling a transition from the first magnitude to the second magnitude to have a straight slope to output the plurality of magnitudes in the pulsed manner, wherein the straight slope is a positive slope or a negative slope.

17. The method of claim 15, wherein said controlling the DC power source includes controlling a transition from the first magnitude to the second magnitude to have a curved slope to output the plurality of magnitudes in the pulsed manner, wherein the curved slope is a positive slope or a negative slope.

18. The method of claim 15, wherein the plurality of polarities include a first polarity and a second polarity, wherein said controlling the DC power source includes controlling the DC power source to have the first polarity for the first time interval in which the current signal has the first magnitude and have the second polarity for the second time interval in which the current signal has the second magnitude.

19. The method of claim 18, wherein said controlling the DC power source includes controlling a transition from the first polarity to the second polarity to have a straight slope to output the plurality of magnitudes in the pulsed manner, wherein the straight slope is a positive slope or a negative slope.

20. The method of claim 18, wherein said controlling the DC power source includes controlling a transition from the first polarity to the second polarity to have a curved slope to output the plurality of magnitudes in the pulsed manner, wherein the curved slope is a positive slope or a negative slope.

21. A method for controlling tilt across a surface of a substrate, comprising:
providing a current signal to a magnetic coil associated with a plasma chamber, wherein the current signal produces a magnetic field within the plasma chamber;
controlling a direct current (DC) power source to output a plurality of magnitudes of the current signal in a pulsed manner during a clock cycle, wherein each of the plurality of magnitudes is output during a process operation; and
repeating the plurality of magnitudes of the current signal during each additional process operation.

22. The method of claim 21, wherein said controlling the DC power source includes controlling the DC power source to modify a polarity of the current signal during the process operation to output the current signal having a plurality of polarities during the process operation, wherein said repeating includes repeating the plurality of polarities during the additional process operation.

23. The method of claim 21, wherein the plurality of magnitudes include a first magnitude and a second magnitude, wherein the first magnitude is output during a first time interval and the second magnitude is output during a second time interval, wherein the first magnitude transitions to the second magnitude to output the plurality of magnitudes in the pulsed manner.
